(19) United States
(12) Patent Application Publication
(10) Pub. No.: US 2004/0085162 A1
(43) Pub. Date: May 6, 2004

(54) Method and apparatus for providing a mixed-initiative dialog between a user and a machine

(76) Inventors: Rajeev Agarwal, Santa Clara, CA (US); Behzad M. Shahshahani, Capitola, CA (US)

Correspondence Address: Jordan M. Becker, BLAKELY, SOKOLOFF, TAYLOR & ZAFMAN LLP, Seventh Floor, 12400 Wilshire Boulevard, Los Angeles, CA, 90025-1026, US

(21) Appl. No.: 09/727,022

(22) Filed: Nov. 29, 2000

(51) Int. Cl. H03H 9/00

(52) U.S. Cl. 333/196

(57) ABSTRACT

A method and apparatus for enabling a mixed initiative dialog to be carried out between a user and a machine are described. A speech-enabled processing system receives an utterance from the user, and the utterance is recognized by an automatic speech recognizer using a set of statistical language models. Prior to parsing the utterance, a dialog manager uses a semantic frame to identify the set of all slots potentially associated with the current task and then retrieves a corresponding grammar for each of the identified slots from an associated reusable dialog component. A natural language parser then parses the utterance using the recognized speech and all of the retrieved grammars. The dialog manager then identifies any slot which remains unfilled after parsing and causes a prompt to be played to the user for information to fill the unfilled slot. Dependencies and constraints may be associated with particular slots.

### FIELD OF THE INVENTION

The present invention pertains to techniques for allowing humans to interact with machines using speech. More particularly, the present invention relates to providing a mixed-initiative dialog between a user and a machine.

### BACKGROUND OF THE INVENTION

Speech-enabled applications (“speech applications”) are rapidly becoming commonplace in everyday life. A speech application may be defined as a machine-implemented application that performs tasks automatically in response to speech of a human user and which responds to the user with audible prompts, typically in the form of recorded or synthesized speech. For example, speech applications may be designed to allow a user to make travel reservations or to buy stock over the telephone without assistance from a human operator.

In a typical speech application, the user's speech is recognized by an automatic speech recognizer and then parsed to fill various slots. A slot is a specific type of information needed by the application to perform a particular task. Parsing is the process of assigning values to slots based on the recognized speech of a user. For example, in a speech application for making travel reservations, a common task might be booking a flight. Accordingly, the slots to be filled for this task might include the departure date, departure time, departure city and destination city.

Conventional speech applications generally use a system-initiated approach, in which the user must respond to the system's prompts rather precisely in order for the responses to be properly interpreted and to complete the requested tasks. Consequently, if the user supplies information different from what a prompt solicited, or information beyond what the prompt solicited, a conventional system may have difficulty correctly interpreting the response. Typically, each prompt is designed to elicit information to fill a particular slot. If the user's response includes information that is not relevant to that slot, the slot may not be filled or it may be filled erroneously. This may result in the user having to repeat the task, causing irritation or frustration for the user.

These difficulties have sparked significant interest in developing mixed-initiative systems. In a mixed-initiative approach, the user's responses are not required to be strictly compliant to the prompts. That is, the user may supply information other than, or in addition to, what was requested by a given prompt, and the system will be able to correctly interpret the response. Ideally, the user should be given the flexibility to fill slots in any order and to fill more than one slot in a single turn. One problem with existing mixed initiative systems, however, is that they are not very flexible. These systems tend to be complex, expensive, and difficult to implement and maintain. In addition, such systems generally are not very portable across applications. It is desirable, therefore, to have a mixed initiative system which overcomes these and other disadvantages of the prior art.

### SUMMARY OF THE INVENTION

The present invention includes a method and apparatus for enabling a mixed initiative dialog to be carried out between a user and a machine. The method includes providing a set of reusable dialog components, and operating a dialog manager to control use of the reusable dialog components based on a semantic frame. The reusable dialog components are individually configured to carry out system initiated aspects of a dialog. In particular embodiments, each of multiple slots is associated with a different reusable dialog component, which provides the grammar and/or a prompt associated with the slot; also, the semantic frame includes a mapping of tasks to slots. Dependencies between slots may be used, among other things, to facilitate confirmation and correction of slot values.

Other features of the present invention will be apparent from the accompanying drawings and from the detailed description which follows.

### BRIEF DESCRIPTION OF THE DRAWINGS

The present invention is illustrated by way of example and not limitation in the figures of the accompanying drawings, in which like references indicate similar elements and in which:

FIG. 1 illustrates a system architecture for performing a mixed initiative dialog;

FIG. 2 illustrates a process for performing a mixed initiative dialog in the system of FIG. 1;

FIG. 3 illustrates a process for performing smart confirmation and correction of slots in the system of FIG. 1; and

FIG. 4 is a dialog state diagram for an illustrative speech-enabled task that can be performed using the system of FIG. 1.

### DETAILED DESCRIPTION

A method and apparatus for performing a mixed-initiative dialog between a user and a machine are described. Note that in this description, references to “one embodiment” or “an embodiment” mean that the feature being referred to is included in at least one embodiment of the present invention. Further, separate references to “one embodiment” in this description do not necessarily refer to the same embodiment; however, neither are such embodiments mutually exclusive, unless so stated and except as will be readily apparent to those skilled in the art. Thus, the present invention can include any variety of combinations and/or integrations of the embodiments described herein.

The method and apparatus are described in detail below, but are briefly described as follows. A system running a speech application receives an utterance from a user, and the utterance is recognized by an automatic speech recognizer using statistical language models. Prior to parsing the utterance, a dialog manager uses a semantic frame to identify the set of all slots potentially associated with the current task and then retrieves a corresponding grammar for each of the identified slots from an associated reusable dialog component. A “grammar” is the set of all allowable words and phrases by a user in response to a particular prompt, including the allowable order of the words and phrases. A natural language parser parses the utterance using the recognized speech and all of the retrieved grammars. The dialog manager then identifies any slot which remains unfilled after parsing and causes a prompt to be played to the user for information to fill the unfilled slot. Reusable, discrete dialog components, such as “speech objects”, are used to provide the grammar and prompt for each task. Dependencies and constraints may be associated with particular slots and used to fill slots more efficiently. Dependencies between slots may be used to perform “smart” confirmation and correction of slot values.

Disambiguation, confirmation, and other subdialogs are handled entirely by the reusable dialog components in a system initiated manner. This approach provides an overall mixed initiative system which includes modularized system initiated subdialogs within reusable dialog components.

A number of critical issues should be considered in creating an effective mixed initiative system. These issues include: how to recognize open-ended speech; how to identify what slots the user is trying to fill; how to obtain the grammars for those slots; how to parse the utterance with those grammars; how to know what parse is the most suitable; how to determine what is the next thing to request from the user; and where to get the appropriate prompt to request that. For most if not all of these issues, there is a variety of ways they could potentially be addressed. However, not all potential approaches will yield an effective mixed initiative system which is also portable across applications, inexpensive, and easy to implement.

In the present invention, the use of statistical language models allows for recognition of open-ended speech. The statistical language model selected for use at any point in time may be specifically adapted for the most-recently played prompt. The system provides effective mixed initiative capability by, among other things, identifying all possible slots for the current task before parsing the utterance and retrieving the corresponding grammars. The appropriate slots are identified using a semantic frame. Accordingly, the user can specify information different from, or in addition to, that which was requested by the system, without causing errors in interpretation. The system will recognize superfluous information and use it to fill other slots that are relevant to the current task. The use of speech objects makes this approach highly portable across applications as well as simplifying and reducing the expense of application development and deployment. Other advantages of the present invention will become apparent from the description which follows.

In this description, a reusable dialog component is a component for controlling a discrete piece of conversational dialog between the user and the system. A “speech object” is a software based implementation of a reusable dialog component. For purposes of illustration only, this description henceforth uses the assumption that the reusable dialog components are speech objects. It will be recognized, however, that other types of reusable dialog components may be used in conjunction with the described technique and system.

Techniques for creating and using such speech objects are described in detail in U.S. patent application Ser. No. 09/296,191 of Monaco et al., filed on Apr. 23, 1999 and entitled, “Method and Apparatus for Creating Modifiable and Combinable Speech Objects for Acquiring Information from a Speaker in an Interactive Voice Response System,” (“the Monaco application”), which is incorporated herein by reference, and which is assigned to the assignee of the present application. The use of speech objects as described in the Monaco application provides a standardized framework which greatly simplifies the development of speech applications. As described in the Monaco application, each speech object generally is designed to fill a particular slot by acquiring the required information from the user. Accordingly, each speech object provides an appropriate prompt for its corresponding slot and includes the grammar for parsing the user's response. Speech objects can be used hierarchically. A speech object may be a user-extensible class, or an instantiation of such a class, defined in an object-oriented programming language, such as Java or C++. Accordingly, speech objects may be reusable software components, such as JavaBeans. The prompts and grammars may be defined as properties of the speech objects.

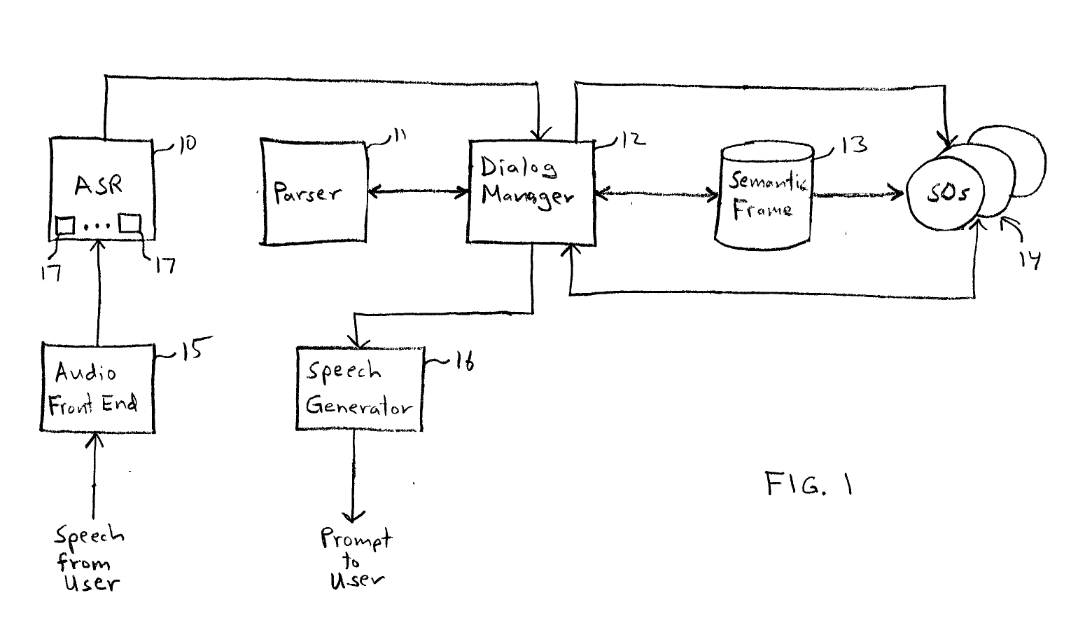

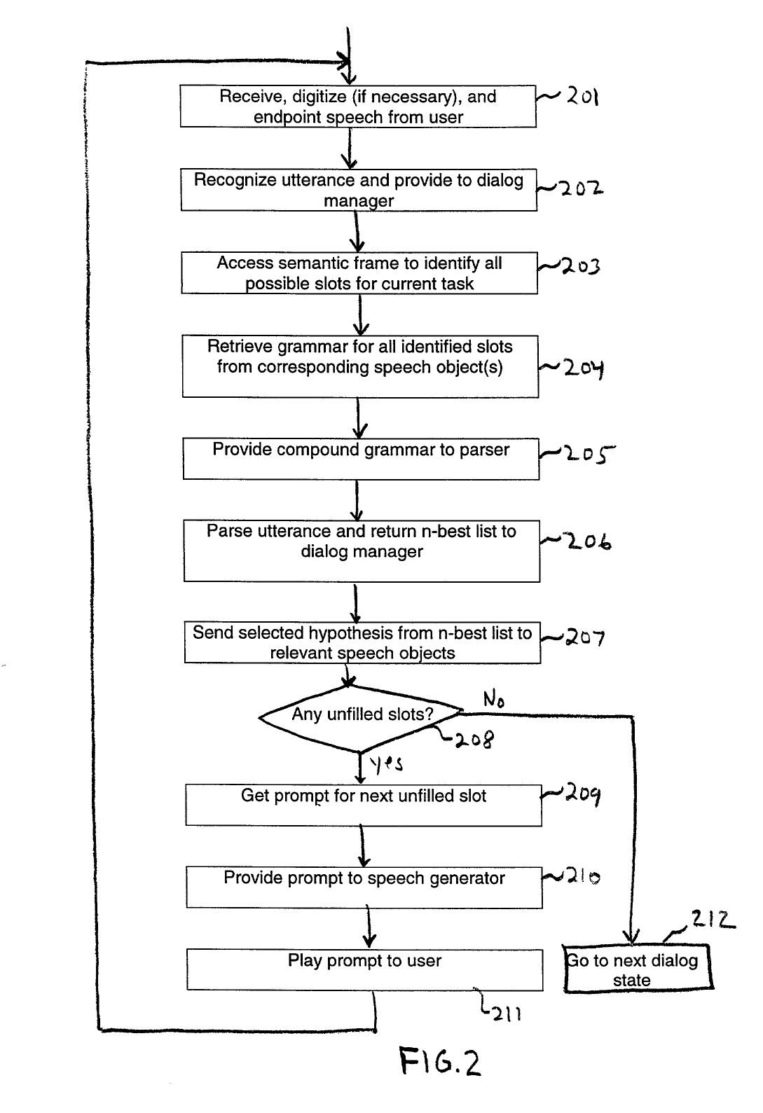

Refer now to FIGS. 1 and 2, which illustrate a system architecture and a process, respectively, for carrying out a mixed initiative dialog for a speech application. The system includes an automatic speech recognizer (ASR) 10, a natural language parser 11, a dialog manager 12, a semantic frame 13, a set of speech objects 14 (of the type described above), an audio front-end 15 and a speech generator 16. The specific details of the speech objects, i.e. the types of slots they are designed to fill, depend upon the domain of the application and the particular tasks which need to be performed.

Referring to FIGS. 1 and 2, in operation, the audio front-end 15 initially receives speech from the user at block 201. The speech from the user may be received over any suitable medium, such as a conventional telephone line, a direct microphone input, a computer network or internetwork (e.g., a local area network or the Internet). The audio front-end 15 includes circuitry for digitizing the input speech waveforms (if not already digitized), endpointing the speech, and extracting feature vectors. The audio front-end 15 may be implemented in, for example, a circuit board in a conventional computer system, such as the type of board available from Dialogic Corporation of Parsippany, N.J. Alternatively, the audio front-end 15 may be implemented in a Digital Signal Processor (DSP) in an end user device, such as a cellular telephone, or any other suitable device. The extracted feature vectors are output by the audio front-end 15 to the ASR 10.

The ASR 10 includes a set of statistical language models 17 of the type which are known in the field of speech recognition. At block 202, the ASR 10 uses the statistical language models 17 to recognize the speech of the user based on the feature vectors. The statistical language model(s) selected for use at any given point in time may be adapted for the most-recently played prompt. That is, the particular statistical language model used at any given point in time may be selected based on which prompt was most-recently played. The ASR 10 may be or may include a speech recognition engine of the type available from Nuance Communications of Menlo Park, California. The output of the ASR 10 is a recognized utterance or an N-best list of hypotheses, which may be in text form, and which is provided to the dialog manager 12.

In contrast with more conventional systems, the illustrated system does not parse the recognized speech (assign values to slots) immediately after recognizing the utterance. Instead, the dialog manager 12 first identifies the set of all possible slots for the current task at block 203. This identification of slots can actually be performed even before recognition occurs in some situations, i.e., situations in which the current task can be identified with certainty regardless of the user's next utterance. The dialog manager 12 determines set of all possible slots for the current task from the semantic frame 13. The semantic frame 13 is a mapping of tasks to corresponding slots and speech objects for the speech application. The semantic frame 13 includes all possible tasks for the current application and an indication of what the corresponding speech objects (and therefore, slots) are for each task. It is assumed that each of the speech objects 14 corresponds to a different slot. The semantic frame 13 may be a look up table or any other suitable data structure.

As an example, assume that the speech application is a simple airline reservation booking system, which uses the following slots: Departure Date, Departure Time, Departure City, Destination, Arrival Time, and Flight Information. Assume further that the application can perform two tasks, Book a Flight and Get Gate Information. Book a Flight allows the user to make a flight reservation. Get Gate Information allows the user to determine the gate for a flight. Book a Flight may have the following slots: Travel Date, Departure Time, Departure City, and Destination. That is, each of these slots must be filled in order to complete the task, Book a Flight. On the other hand, a task may have two or more alternatives sets of slots, such that the task can be performed by filling more than one unique combination of slots. For example, the following combinations of slots may be associated with the task, Get Gate Information, where brackets indicate the groupings of slots: [Flight Information], or [Departure Time, Destination, and Arrival Time], or [Departure Time, Departure City, and Flight Information]. Hence, the task Get Gate Information may be performed by filling only the slot, Flight Information; or by filling the slots, Departure Time, Destination, and Arrival Time; or by filling the slots, Departure Time, Departure City, and Flight Information.

Hence, the semantic frame 13 maintains a database of all such combinations of speech objects (and therefore, slots) for all tasks associated with the application. Preferably, the dialog manager 12 maintains knowledge of which task or tasks correspond to each dialog state. Accordingly, the dialog manager 12 can determine, for any particular task, the set of all possible slots by using the information in the semantic frame 13. As noted, this is normally done after recognition of the utterance but before the utterance is parsed, in contrast with conventional systems. If the dialog manager 12 does not know which task applies, it can simply retrieve all grammars for the current application from the speech objects 14, again, using the semantic frame 13 to identify the speech objects.

Note that the Monaco application describes the use of a speech object class called SODialogManager, which may be used to create (among other things) compound speech objects. The dialog manager 12 described herein may be implemented as a subclass of SODialogManager.

Referring again to FIGS. 1 and 2, after the set of all potential slots is identified by the dialog manager 12 from the semantic frame 13, at block 204 the dialog manager 12 obtains the grammars 25 for all of the identified slots from the corresponding speech objects 14. The grammars are then forwarded to the natural language parser 11 by the dialog manager 12 at block 205. The parser 11 then parses the utterance and returns to dialog manager 12 an n-best list of possible slot-value sets that are filled at block 206.

Next, at block 207 the dialog manager 12 selects a set (using any conventional algorithm) from the n-best list and sends it to each of the relevant speech objects 14. If speech objects of the type described in the Monaco application are used, this operation (block 207) may involve setting an external recognition result parameter, ExternalRecResult, of each of the relevant speech objects 14, using the selected hypothesis from the n-best list, and then invoking those speech objects. As described in the Monaco application, each speech object provides its own implementation of a Result class, to store a recognition result when the speech object invokes a speech recognizer. Setting ExternalRecResult of a speech object essentially tells the speech object not to invoke the ASR 10 on its own. However, the speech object will still need to perform disambiguation of the ExternalRecResult and/or to set its own Result accordingly. This will allow subsequent access to its Result, if necessary.

Next, at block 208 the dialog manager 12 consults the semantic frame 13 to identify the next unfilled slot, if any. If there are no unfilled slots, the dialog manager initiates the next dialog state at block 212. If there is an unfilled slot, then at block 209 the dialog manager obtains the prompt for the next unfilled slot from the associated speech object 14. The dialog manager 12 then passes the prompt to the speech generator 16 at block 210, which plays the prompt to the user in the form of recorded or synthesized speech at block 211, to request information for filling the unfilled slot. The prompt may be played to the user over the same medium used to receive the user's speech (e.g., a telephone line or a computer network). The foregoing process is invoked and repeated as necessary to allow the user to complete the desired tasks.

Note that an advantage of the present invention is that (slot-specific) disambiguation, confirmation, and other subdialogs are handled entirely by the speech objects (or other reusable dialog components) in a system initiated manner. Consequently, the dialog manager 12 does not need to perform such operations or to have any knowledge of slot-specific information related to such operations. This provides an overall mixed initiative system which uses modularized system initiated subdialogs within reusable dialog components.

The mixed initiative capability can be enhanced in the illustrated system by configuring the system to intelligently utilize constraints upon slots and dependencies between slots. A constraint upon a slot is a limit upon the set of potential values that can fill the slot. Dependencies between slots allow the system to fill a slot without prompting based on the value used to fill a related slot, using knowledge of a relationship between the slots. In addition, slot dependencies can also be used to retroactively fill slots, the values of which were not explicitly spoken, based on values used to fill other slots. Dependencies and constraints can be coded by the application developer at design time, using properties of the speech objects. For example, in a speech application for buying and selling stocks, the task Buy Shares may include an Order Type slot to specify the type of purchase order (e.g., market order, limit order, etc.). The Buy Shares task may also include a Limit Price slot to specify a limit price when the order is a limit order. Consequently, if a response from the user is interpreted to include a limit price, that fact can be used to immediately fill the Order Type slot (i.e., to fill the Order Type slot with “limit”), even if the user has not yet been prompted for or explicitly mentioned the Order Type. Hence, the system can intelligently use dependencies between slots to fill slots out of order (i.e., in a sequence different from the prompt sequence).

In practice, this example might occur as follows. The system initially outputs an opening prompt to a user, such as, “How can I help you today?” The user responds with the statement, “Um, I want to buy 100 shares of Nuance.” The system then responds with the prompt, “Is this a market order or a limit order?” to try to fill the Order Type slot. Instead of answering the prompt directly, the user may say, “Oh, the limit price is two hundred dollars, good for the day.” Because the system maintains knowledge of dependencies between slots, the system is able to immediately identify the order type as a limit order and fill the Order Type slot accordingly with the value, “limit”. At the same time, the system can also fill the Order Price and Time Limit slots.

After filling the slots associated with a task, it is desirable to obtain confirmation from the user that the results are correct and to correct any errors. The mixed initiative architecture and technique described above facilitate “smart” confirmation and correction of dialog results. More specifically, during the confirmation and correction process, information on slot dependencies from the semantic frame can be used to identify and automatically invoke speech objects that were not previously invoked (i.e., not relevant), or to avoid invoking speech objects that are no longer relevant in view of the corrected slot values.

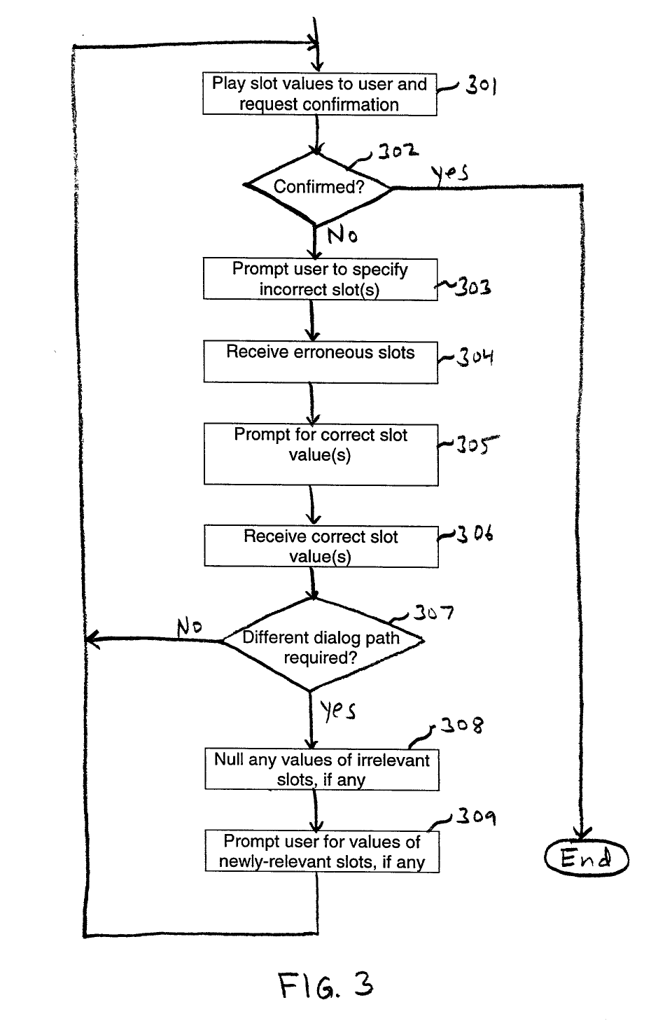

A separate speech object may be used to perform these confirmation and correction operations. FIG. 3 shows a process that may be performed by such a speech object (or other similar component), according to one embodiment. Initially, the slot values for the various slots are played to the user, and confirmation of the values is requested at block 301. An example of this operation is to play the prompt, “Did you say, ‘Book a flight from San Francisco to Miami on November 16?’” If the slot values are confirmed by the user at block 302, the process ends. If the user does not confirm, then at block 303 the user is asked which slots needs to be changed, e.g., the system might prompt, “Which part of that was incorrect?” The erroneous slot (name or value) is then received from the user (e.g., “The date is wrong.”) at block 304. The system then prompts for the correct (new) value for that slot at 305, and the correct slot value is received at block 306. Next, at block 307 it is determined whether the new slot value leads the dialog along a different path than before the correction, based on dependencies indicated in the semantic frame. If so, the values of any slots that are no longer relevant (no longer in the dialog path) are nulled at block 308. At block 309 the user is prompted for any new slot values needed (based on the dependencies) for the corrected dialog path, by invoking the corresponding speech object(s). The process then loops back to block 301. If the new slot value does not require a different dialog path at block 307, then the process loops back to block 301 from that point.

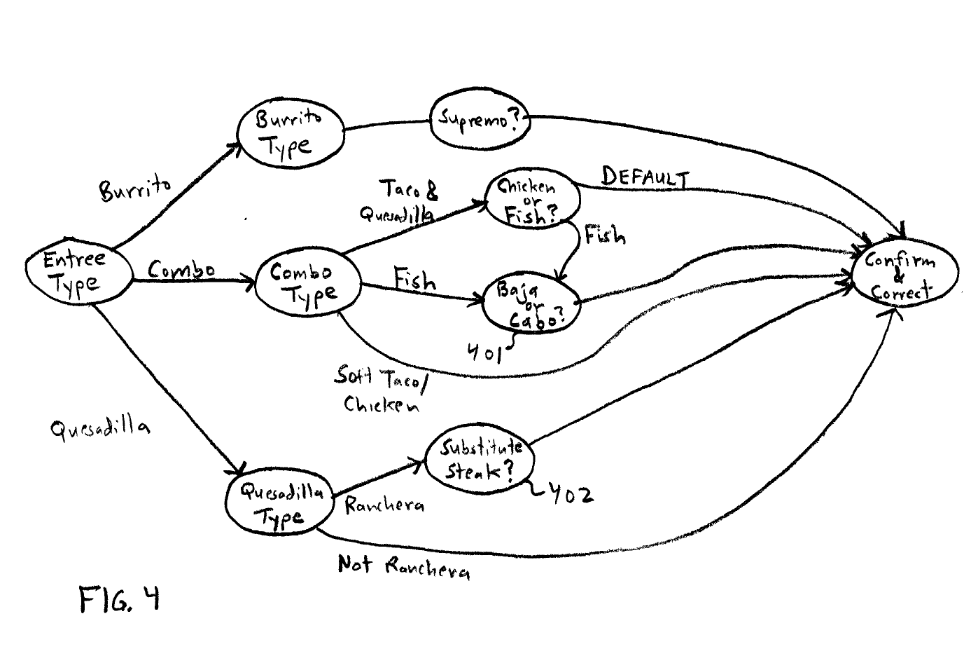

An example of the application of this process will now be provided in connection with FIG. 4. FIG. 4 is a dialog state diagram for an illustrative speech-enabled task that can be performed using the above-described system. The task is ordering an entree for a Mexican-style meal. The states (indicated as ovals) correspond to slots, with the exception of the last state, Confirm & Correct. In the Confirm & Correct state, the above-described confirmation and correction process is executed.

There are various possible paths through the dialog (indicated by the arrows connecting the ovals), and the particular path taken depends upon how the slots are filled. For example, for the Entree Type slot, the user may select the values “Burrito”, “Quesadilla”, or “Combo”. If the user selects “Combo”, he is prompted to select either “Taco & Quesadilla”, “Fish”, or “Soft Taco /Chicken” as values for the Combo Type slot. However, if he selects “Quesadilla”, he is prompted to specify whether he wants “Ranchera style”.

Assume now that after completing the dialog, the system “thinks” the user ordered a Fish Combo, Baja style (state 401). During the confirmation and correction process, however, the user indicates he actually ordered a “Steak Quesadilla” (state 402). Accordingly, based on the dependencies indicated in the semantic frame, the system determines from this response by the user that the values for the slots “Combo Type” and “Baja or Cabo” should be nulled. Further, the system now knows that the speech objects for those slots should not be invoked again. Likewise, the system determines that the value of the “Substitute Steak” slot should be “yes”, and that the value of the “Quesadilla Type” slot should be “Ranchera”. Note that the “Quesadilla Type” slot is filled in this example even though the user did not explicitly give its value; this is done by using the known dependencies between slots (in this case, the fact that only a Ranchera-type quesadilla allows steak to be substituted).

With the above-described functionality in mind, the components illustrated in FIG. 1 may be constructed through the use of conventional techniques, except as otherwise noted herein. These components may be constructed using software with conventional hardware, customized circuitry, or a combination thereof.

For example, the illustrated system may be implemented using one or more conventional processing systems, such as a personal computer (PC), workstation, hand-held computer, Personal Digital Assistant (PDA), etc. Thus, the system may be contained in one such processing system or it may be distributed between two or more such processing systems, which may be connected on a wired or wireless network. Each such processing system may be assumed to include a central processing unit (CPU) (e.g., a microprocessor), random access memory (RAM), read-only memory (ROM), and a mass storage device, connected to each other by a bus system. The mass storage device may include any suitable device for storing large volumes of data, such as magnetic disk or tape, magneto-optical (MO) storage device, or any of various types of Digital Versatile Disk (DVD) or compact disk (CD) based storage, flash memory, etc.

Also coupled to the aforementioned components may be components such as: an audio front end, a display device, a data communication device, and other input/output (I/O) devices. The audio front end allows the computer system to receive an input audio signal representing speech from the user and, therefore, corresponds to the audio front-end 15 illustrated in the Figure. Hence, the audio front and includes circuitry to receive and process the speech signal, which may be received from a microphone, a telephone line, a network interface, etc., and to transfer such signal onto the aforementioned bus system. The audio interface may include one or more DSPs, general-purpose microprocessors, microcontrollers, ASICs, PLDs, FPGAs, A/D converters, and/or other suitable components.

The aforementioned data communication device may be any device suitable for enabling the processing system to communicate data with another processing system over a network over a data link, as may be the case when the illustrated system is implemented using a distributed architecture. Accordingly, the data communication device may be, for example, an Ethernet adapter, a conventional telephone modem, a wireless modem, an Integrated Services Digital Network (ISDN) adapter, a cable modem, a Digital Subscriber Line (DSL) modem, or the like.

Note that some of the aforementioned components may be omitted in certain embodiments, and certain embodiments may include additional or substitute components that are not mentioned here. Such variations will be readily apparent to those skilled in the art. As an example of such a variation, the functions of an audio interface and a data communication device may be provided in a single device. As another example, the I/O components might further include a microphone to receive speech from the user and audio speakers to output prompts, along with associated adapter circuitry. As yet another example, a display device may be omitted if the processing system requires no direct interface to a user.

Thus, a method and apparatus for performing a mixed-initiative dialog between a user and a machine have been described. Although the present invention has been described with reference to specific exemplary embodiments, it will be evident that various modifications and changes may be made to these embodiments without departing from the broader spirit and scope of the invention as set forth in the claims. Accordingly, the specification and drawings are to be regarded in an illustrative sense rather than a restrictive sense.

What is claimed is:

1. A method of enabling a mixed initiative dialog to be carried out between a user and a machine, the method comprising:
providing a set of reusable dialog components; and
operating a dialog manager to control use of the reusable dialog components based on a semantic frame, wherein the reusable dialog components are individually configured to carry out system initiated aspects of a dialog.

2. A method as recited in claim 1, wherein the reusable dialog components are configured to perform disambiguation and confirmation actions specific to semantic slots associated with a current task, such that the dialog manager does not perform said disambiguation and confirmation actions.

3. A method as recited in claim 1, wherein the semantic frame contains a map of tasks to corresponding semantic slots.

4. A method as recited in claim 1, wherein said operating the dialog manager comprises:
(a) parsing an utterance using grammars from the set of reusable dialog components;
(b) after said parsing, using a prompt from one of the reusable dialog components to request information from the user to fill an unfilled slot; and
(c) automatically repeating said (b), if necessary, to fill any additional unfilled slots associated with the current task.

5. A method of enabling a mixed initiative dialog to be carried out between a user and a machine, the method comprising:
(a) receiving speech from the user, the speech representing an utterance;
(b) recognizing the utterance;
(c) identifying the set of all slots potentially associated with a current task; and
(d) using a set of reusable dialog components corresponding to said set of slots to fill the slots associated with the current task, including
(d)(1) parsing the utterance using grammars from the set of reusable dialog components, and
(d)(2) after said parsing, using a prompt from one of the reusable dialog components to request information from the user to fill an unfilled slot.

6. A method as recited in claim 5, further comprising automatically repeating said (d)(2), as necessary, to fill additional unfilled slots associated with the current task.

7. A method as recited in claim 5, wherein each of the slots represents an item of information which may be acquired from the user.

8. A method as recited in claim 5, wherein said identifying the set of all slots potentially associated with a current task is carried out prior to said parsing the utterance.

9. A method as recited in claim 5, wherein said parsing the utterance comprises filling one or more of the possible slots with corresponding values.

10. A method as recited in claim 5, wherein said identifying the set of all slots potentially associated with a current task comprises using a semantic frame that maps tasks performable in response to speech from the user to corresponding slots, to identify the set of all slots potentially associated with the current task.

11. A method as recited in claim 5, wherein each of the reusable dialog components is a speech object embodying an instantiation of a speech object class.

12. A method as recited in claim 5, wherein said recognizing comprises using a set of statistical language models so as to be capable of recognizing open-ended speech.

13. A method as recited in claim 12, wherein at least one of the statistical language models is specifically adapted for a most-recently played prompt.

14. A method as recited in claim 5, wherein a dependency exists between two or more of the slots.

15. A method as recited in claim 14, further comprising identifying a dependency between two of the slots, wherein said parsing the utterance comprises filling one of the slots based on the dependency and a value used to fill another slot.

16. A method as recited in claim 5, wherein the dialog is for accomplishing a task, and wherein the method further comprises confirming and correcting slots filled during the dialog, including:
determining that one of the slots is incorrect;
prompting the user for a corrected value for the slot;
receiving the corrected value from the user; and
using the corrected value and stored information on dependencies between the slots to control further dialog for accomplishing the task.

17. A method of enabling a mixed initiative dialog to be carried out between a user and a machine, the method comprising:
(a) receiving speech from the user, the speech representing an utterance;
(b) recognizing the utterance;
(c) identifying the set of all slots potentially associated with a current task;
(d) retrieving a corresponding grammar for each of the identified slots from one of a plurality of reusable dialog components;
(e) parsing the utterance using the recognized speech and the retrieved grammars. (f) identifying one of the slots which remains unfilled after parsing the utterance;
(g) obtaining a prompt for said slot which remains unfilled from a corresponding one of the reusable dialog components;
(h) playing the prompt to the user; and
(i) repeating said (a), (b), (e), (f), (g) and (h) so as to fill all of the slots associated with the current task.

18. A method as recited in claim 17, wherein each of the slots represents an item of information which may be acquired from the user.

19. A method as recited in claim 17, wherein said identifying the set of all slots potentially associated with a current task is carried out prior to said parsing the utterance.

20. A method as recited in claim 17, wherein said parsing the utterance comprises filling one or more of the possible slots with corresponding values.

21. A method as recited in claim 17, wherein said identifying the set of all slots potentially associated with a current task comprises using a mapping of tasks performable in response to speech from the user to corresponding slots, to identify the set of all slots potentially associated with the current task.

22. A method as recited in claim 17, wherein each of the reusable dialog components is a speech object embodying an instantiation of a speech object class.

23. A method as recited in claim 17, wherein said recognizing comprises using a set of statistical language models so as to be capable of recognizing open-ended speech.

24. A method as recited in claim 23, wherein at least one of the statistical language models is specifically adapted for a most-recently played prompt.

25. A method as recited in claim 17, wherein a dependency exists between two or more of the slots.

26. A method as recited in claim 17, further comprising identifying a dependency between two of the slots, wherein said parsing the utterance comprises filling one of the slots based on the dependency and a value used to fill another slot.

27. A method as recited in claim 17, wherein the dialog is for accomplishing a task, and wherein the method further comprises confirming and correcting slots filled during the dialog, including:
determining that one of the slots is incorrect;
prompting the user for a corrected value for the slot;
receiving the corrected value from the user; and
using the corrected value and stored information on dependencies between the slots to control further dialog for accomplishing the task.

28. A method of carrying out a mixed initiative dialog between a user and a machine, the method comprising:
receiving speech from the user, the speech representing an utterance;
recognizing the utterance using an automatic speech recognizer;
identifying the set of all slots potentially associated with a current task prior to parsing the utterance, each slot representing an item of information which may be acquired from the user;
for each of the possible slots, retrieving a corresponding grammar from a corresponding one of a plurality of reusable dialog components;
using the recognized speech and the retrieved grammars to parse the utterance, including filling one or more of the possible slots with corresponding values;
identifying one of the slots which remains unfilled;
accessing a prompt for the slot which remains unfilled from a corresponding one of the reusable dialog components; and
playing the prompt to the user.

29. A method as recited in claim 28, wherein a plurality of tasks may be performed in response to speech from the user, and wherein said identifying the set of all slots potentially associated with a current task comprises using a semantic frame which includes a mapping of tasks to slots to identify the set of all slots potentially associated with the current task.

30. A method as recited in claim 29, wherein of the reusable dialog components is an instantiation of a speech object class.

31. A method as recited in claim 28, wherein said recognizing comprises using a set of statistical language models so as to be capable of recognizing open-ended speech.

32. A method as recited in claim 31, wherein at least one of the statistical language models is specifically adapted for a most-recently played prompt.

33. A method as recited in claim 28, wherein a dependency exists between two or more of the slots.

34. A method as recited in claim 33, further comprising:
identifying a dependency between two of the slots; and
filling one of the slots based on the dependency and a value used to fill another slot.

35. A method as recited in claim 28, wherein the dialog is for accomplishing a task, and wherein the method further comprises confirming and correcting slots filled during the dialog, including:
determining that one of the slots is incorrect;
prompting the user for a corrected value for the slot;
receiving the corrected value from the user; and
using the corrected value and stored information on dependencies between the slots to control further dialog for accomplishing the task.

36. An apparatus for enabling a mixed initiative dialog to be carried out between a user and a machine, the apparatus comprising:
means for receiving speech from the user, the speech representing an utterance;
means for recognizing the utterance;
means for identifying the set of all slots potentially associated with a current task; and
means for using a set of reusable dialog components corresponding to said set of slots to fill the slots associated with the current task, including
means for parsing the utterance using grammars from the set of reusable dialog components, and
means for using, after said parsing, a prompt from one of the reusable dialog components to request information from the user to fill an unfilled slot.

37. An apparatus as recited in claim 36, further comprising means for automatically repeating said using a prompt from one of the reusable dialog components to request information from the user to fill an unfilled slot, as necessary, to fill any additional unfilled slots associated with the current task.

38. An apparatus as recited in claim 36, wherein each of the slots represents an item of information which may be acquired from the user.

39. An apparatus as recited in claim 36, wherein the means for identifying the set of all slots potentially associated with a current task is carried out prior to said parsing the utterance.

40. An apparatus as recited in claim 36, wherein the means for identifying the set of all slots potentially associated with a current task comprises means for using a semantic frame that maps tasks performable in response to speech from the user to corresponding slots, to identify the set of all slots potentially associated with the current task.

41. An apparatus as recited in claim 36, wherein each of the reusable dialog components is an instantiation of a speech object class.

42. An apparatus as recited in claim 36, wherein the means for recognizing comprises means for using a set of statistical language models so as to be capable of recognizing open-ended speech.

43. An apparatus as recited in claim 42, wherein at least one of the statistical language models is specifically adapted for a most-recently played prompt.

44. An apparatus as recited in claim 36, wherein a dependency exists between two or more of the slots, the apparatus further comprising the means for identifying a dependency between two of the slots, wherein said parsing the utterance comprises filling one of the slots based on the dependency and a value used to fill another slot.

45. An apparatus as recited in claim 36, wherein the dialog is for accomplishing a task, and wherein the apparatus further comprises means for confirming and correcting slots filled during the dialog, including:
means for determining that one of the slots is incorrect;
means for prompting the user for a corrected value for the slot;
means for receiving the corrected value from the user; and
means for using the corrected value and stored information on dependencies between the slots to control further dialog for accomplishing the task.

46. A machine-readable storage medium embodying instructions for execution by a machine, which instructions configure the machine to perform a method for enabling a mixed initiative dialog to be carried out between a user and the machine, the method comprising:
providing a set of reusable dialog components; and
operating a dialog manager to control use of the reusable dialog components based on a semantic frame, wherein the reusable dialog components are individually configured to carry out system initiated aspects of a dialog.

47. A machine-readable storage medium as recited in claim 46, wherein the reusable dialog components are configured to perform disambiguation and confirmation actions specific to semantic slots associated with a current task, such that the dialog manager does not perform said disambiguation and confirmation actions.

48. A machine-readable storage medium as recited in claim 46, wherein the semantic frame contains a map of tasks to corresponding semantic slots.

49. A machine-readable storage medium as recited in claim 46, said operating the dialog manager comprises:
(a) parsing an utterance using grammars from the set of reusable dialog components;
(b) after said parsing, using a prompt from one of the reusable dialog components to request information from the user to fill an unfilled slot; and
(c) automatically repeating said (b), if necessary, to fill any additional unfilled slots associated with the current task.

50. A device for enabling a mixed initiative dialog to be carried out between a user and a machine, the device comprising:
a set of reusable dialog components individually configured to carry out system initiated aspects of a dialog;
a semantic frame; and
a dialog manager to control use of the reusable dialog components based on the semantic frame.

51. A device as recited in claim 50, wherein the reusable dialog components are configured to perform disambiguation and confirmation actions specific to semantic slots associated with a current task, such that the dialog manager does not perform such disambiguation and confirmation actions.

52. A device as recited in claim 50, wherein the semantic frame contains a map of tasks performable in response to speech from the user to corresponding semantic slots.

53. A device as recited in claim 50, wherein the dialog manager is configured to:
(a) parse an utterance using grammars from the set of reusable dialog components;
(b) after said parsing, use a prompt from one of the reusable dialog components to request information from the user to fill an unfilled slot; and
(c) automatically repeat said (b), if necessary, to fill any additional unfilled slots associated with the current task.

54. A device for carrying out a mixed initiative dialog between a user and a machine, the device comprising:
an automatic speech recognizer to recognize an utterance in speech received from the user using a set of statistical language models;
a set of reusable dialog components;
a dialog manager to use a semantic frame to identify the set of all slots potentially associated with a current task prior to parsing of the utterance, and to retrieve a corresponding grammar for each possible slot from a corresponding one of the reusable dialog components, each slot representing an item of information which may be acquired from the user; and
a natural language parser to receive the retrieved grammars and to parse the utterance using the retrieved grammars, including filling one or more of the possible slots with corresponding values;
wherein the dialog manager further is to identify one of the slots which remains unfilled following said filling, to obtain a prompt for the slot which remains unfilled from a corresponding one of the reusable dialog components, and to cause the prompt to be played to the user to request information for filling the slots which remains unfilled.

55. A device as recited in claim 54, wherein the dialog manager is a reusable dialog component.

56. A method as recited in claim 54, wherein at least one of the statistical language models is specifically adapted for a most-recently played prompt

57. A device as recited in claim 54, wherein a dependency exists between two or more of the slots, and wherein the dialog manager is further configured:
to identify a dependency between two of the slots; and
to fill one of the slots based on the dependency and a value used to fill another slot.

58. A method of confirming and correcting slots filled during a dialog between a user and a machine, the dialog for accomplishing a task, the method comprising:
determining that one of a plurality of slots is incorrect;
prompting the user for a corrected value for the slot;
receiving the corrected value from the user; and
using the corrected value and stored information on dependencies between the slots to control further dialog for accomplishing the task

59. A method as recited in claim 58, wherein said using the corrected value and information on dependencies between the slots to control a revised dialog flow comprises determining one or more reusable dialog components to be invoked, to obtain values for slots.

60. A method as recited in claim 59, wherein during the dialog, at least one of the reusable dialog components has not previously been invoked, and a corresponding slot has not previously been filled.

61. A method as recited in claim 58, wherein the information on dependencies is contained within a semantic frame including a mapping of tasks to slots.
